(19) United States
(12) Patent Application Publication
(10) Pub. No.: US 2024/0412980 A1
(43) Pub. Date: Dec. 12, 2024

(54) SEMICONDUCTOR DEVICE WITH INTERCONNECTS FORMED THROUGH ATOMIC LAYER DEPOSITION

(71) Applicant: Micron Technology, Inc., Boise, ID (US)

(72) Inventor: Wei Zhou, Boise, ID (US)

(21) Appl. No.: 18/667,983

(22) Filed: May 17, 2024

Related U.S. Application Data
(60) Provisional application No. 63/471,896, filed on Jun. 8, 2023.

(51) Int. Cl. H01L 21/3205; H01L 23/00; H01L 23/528; H01L 23/532

(52) U.S. Cl. CPC H01L 21/32051; H01L 23/5283; H01L 23/53209; H01L 23/5329; H01L 24/05; H01L 24/08; H01L 2224/05647; H01L 2224/08147; H01L 2924/351

(57) ABSTRACT

A semiconductor device assembly is provided. The semiconductor device assembly includes a first semiconductor die and a second semiconductor die. The first semiconductor die has a first layer of dielectric material and a first conductive pad disposed in a first opening of the first layer of dielectric material. The second semiconductor die has a second layer of dielectric material facing the first layer of dielectric material and a second conductive pad disposed in a second opening of the second layer of dielectric material and corresponding to the first conductive pad. A spacer extends between the first layer of dielectric material and the second layer of dielectric material. A conductive material is disposed between the first conductive pad and the second conductive pad (e.g., through atomic layer deposition (ALD)) to implement an interconnect electrically coupling the first semiconductor die and the second semiconductor die.

### CROSS-REFERENCE TO RELATED APPLICATION(S)

The present application claims priority to U.S. Provisional Patent Application No. 63/471,896, filed Jun. 8, 2023, the disclosure of which is incorporated herein by reference in its entirety.

### TECHNICAL FIELD

The present disclosure generally relates to semiconductor device assemblies and more particularly relates to a stacked semiconductor device with interconnects formed through atomic layer deposition (ALD).

### BACKGROUND

Microelectronic devices generally have a die (e.g., a chip) that includes integrated circuitry with a high density of very small components. Typically, dies include an array of bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of a semiconductor device assembly in accordance with an embodiment of the present technology.

FIGS. 2-6 illustrate simplified schematic plan and cross-sectional views of a series of steps for fabricating semiconductor device assemblies in accordance with an embodiment of the present technology.

FIG. 7 illustrates a simplified schematic cross-sectional view of a semiconductor device assembly in accordance with an embodiment of the present technology.

FIG. 8 illustrates a schematic view of a system that includes a semiconductor device assembly configured in accordance with an embodiment of the present technology.

FIG. 9 illustrates a method of fabricating a semiconductor device assembly in accordance with an embodiment of the present technology.

### DETAILED DESCRIPTION

Computing devices often include semiconductor devices to implement processors, memory, or other function features. Semiconductor devices can be stacked to increase the number of circuit elements implemented within the device without increasing the device footprint. Many stacked semiconductor devices utilize hybrid bonding to form vertical interconnects. Hybrid bonding exploits the volumetric expansion of a conductive material (e.g., copper) to form vertical interconnects through openings in bonded layers of dielectric material. For example, two semiconductor dies may be aligned such that a conductive pad located in an opening of a layer of dielectric material on one of the semiconductor dies aligns with a conductive pad located in an opening of a layer of dielectric material on the other semiconductor die. The layer of dielectric material at each of the semiconductor dies can be bonded, and the conductive pads may be heated, thereby causing them to expand toward one another.

Ideally, the conductive pads expand and, through diffusion, form metal-metal interconnects within the bonded layers of dielectric material. In other cases, however, the spacing between the conductive pads, which can result from difficult to control chemical-mechanical planarization (CMP) processes, can create under-expanded or over-expanded interconnects that limit the reliability of the semiconductor device. For example, conductive pads may be spaced too far apart from one another, which can leave voids between the interconnects that can short the semiconductor device. Alternatively, the conductive pads may be spaced too close together, which can result in the interconnects separating the bonds between the layers of dielectric material and thereby reducing the mechanical strength of the semiconductor device assembly.

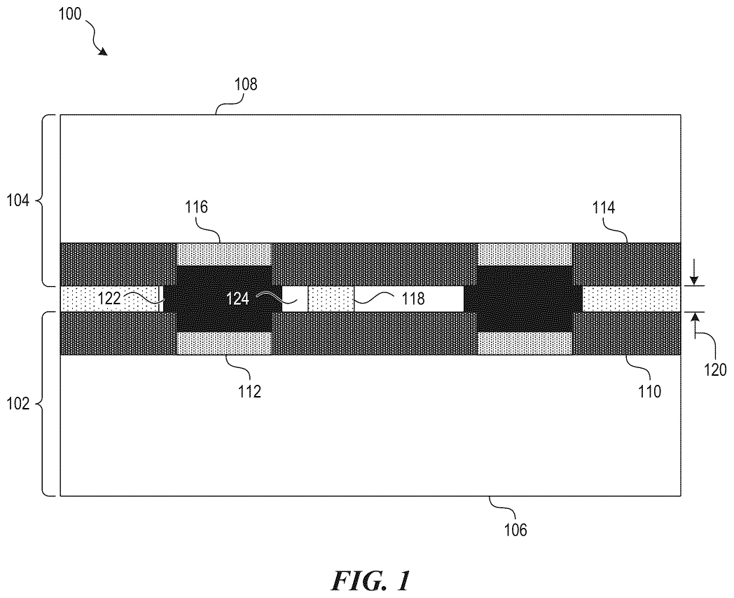

To solve these problems and others, the present technology discloses a semiconductor device with interconnects formed through atomic layer deposition (ALD). The semiconductor device includes a first semiconductor die and a second semiconductor die. The first semiconductor die has a first layer of dielectric material and a first conductive pad disposed in a first opening of the first layer of dielectric material. The second semiconductor die has a second layer of dielectric material facing the first layer of dielectric material and a second conductive pad disposed in a second opening of the second layer of dielectric material and corresponding to the first conductive pad. A spacer extends between the first layer of dielectric material and the second layer of dielectric material. A conductive material is disposed between the first conductive pad and the second conductive pad (e.g., through ALD) to implement an interconnect electrically coupling the first semiconductor die and the second semiconductor die. In doing so, a reliable semiconductor device can be assembled, an example of which is illustrated in FIG. 1.

FIG. 1 illustrates a simplified schematic cross-sectional view of a semiconductor device assembly 100 that includes a semiconductor die 102 and a semiconductor die 104 electrically coupled with one another. The semiconductor die 102 can be implemented on a substrate 106, which can be a wafer-level substrate implementing multiple semiconductor dies or a die-level substrate implementing a singulated semiconductor die. The semiconductor die 104 can similarly be implemented on a substrate 108, which can be a wafer-level or die-level substrate. Accordingly, the semiconductor device assembly 100 can be formed through wafer-to-wafer bonding, chip-to-wafer bonding, or chip-to-chip bonding. The semiconductor die 102 and the semiconductor die 104 can be coupled in a front-to-front arrangement, a front-to-back arrangement, or a back-to-back arrangement. In this way, the semiconductor die 102 or the semiconductor die 104 can include through-silicon vias (TSVs) (not shown) extending through the substrate 106 or the substrate 108, respectively, to provide electrical connection with circuitry at a front side through exposed TSVs at the back side.

A layer of dielectric material 110 (e.g., silicon oxide, silicon nitride, silicon carbide, silicon carbon nitride) can be disposed at the semiconductor die 102 to implement a passivation layer. The layer of dielectric material 110 can have one or more openings, through which contact pads 112 (e.g., copper pads) disposed at the semiconductor die 102 are exposed. The contact pads 112 can be recessed from the layer of dielectric material 110 (e.g., by between 5 and 10 nanometers), for example, due to dishing from CMP. The contact pads 112 can connect to circuitry (e.g., traces, lines, vias) to enable additional circuit components to be electrically coupled with the semiconductor die 102 and provide functionality (e.g., power, ground, input/output (I/O) signaling) to the semiconductor die 102. A layer of dielectric material 114 can be disposed on the semiconductor die 104 such that the layer of dielectric material 114 faces the layer of dielectric material 110. The layer of dielectric material 114 can have openings that expose contact pads 116, which correspond to the contact pads 112 disposed on the semiconductor die 102.

In contrast to other semiconductor devices, the layer of dielectric material 114 and the layer of dielectric material 110 do not necessarily contact one another. Instead, a spacer 118 can be disposed between the layer of dielectric material 110 and the layer of dielectric material 114 to maintain a particular spacing between the semiconductor die 102 and the semiconductor die 104. In doing so, the specifications of the semiconductor device assembly 100 can be controlled. The spacer 118 can be disposed at and extending from the layer of dielectric material 110 or the layer of dielectric material 114. In some cases, the spacer 118 need not cover the entire layer of dielectric material 110 or the layer of dielectric material 114. Instead, the spacer 118 can be a stand-alone structure covering only a portion of the layer of dielectric material 110 or the layer of dielectric material 114. In aspects, the spacer 118 can include a dielectric material (e.g., a same or different dielectric material as the layer of dielectric material 110 or the layer of dielectric material 114) or a polymer. The spacer 118 can have a thickness 120 (e.g., measured perpendicularly from a surface at which the spacer 118 is disposed) less than 100 nanometers, less than 200 nanometers, less than 500 nanometers, and so on. In some cases, a bond can be formed between the spacer 118 and the layer of dielectric material opposite the layer of dielectric material at which the spacer 118 is disposed. For example, if the spacer 118 is disposed at the layer of dielectric material 110, a distal end of the spacer 118 may bond (e.g., fusion bond) with the layer of dielectric material 114.

Conductive material 122 (e.g., a tin-free, lead-free, or non-solder material) can be disposed between the contact pads 112 and the contact pads 116 to implement interconnects that electrically couple the semiconductor die 102 and the semiconductor die 104. The conductive material 122 can be disposed through ALD. In aspects, ALD is a process through which material may be deposited at a fine granularity (e.g., subnanometer precision). However, due to this precision, ALD may take substantially longer than other material deposition techniques (e.g., deposition rate of 100-300 nanometers/hour). Accordingly, ALD can be used for highly controlled deposition within small spaces. In the illustrated example, ALD is used to deposit the conductive material 122 between the contact pads 112 and the contact pads 116. As a result, the conductive material 122 can implement interconnects with a size less than 100 nanometers, less than 200 nanometers, less than 500 nanometers, and so on. Any number of conductive materials can be used to implement the interconnects. For example, the conductive material 122 can include, among others, copper, aluminum, silver, or gold. In some cases, the conductive material 122 can include cobalt due to its advantageous material properties with respect to ALD.

The interconnects formed through the techniques described herein may differ from those formed through other bonding techniques, such as hybrid bonding. For example, hybrid bonding may exploit the thermal expansion properties of conductive pads to form metal-metal interconnects from a single conductive material. In a hybrid bonding process, the connections between conduct pads 112 and contact pads 116 are formed by a high temperature annealing process where the contact pads 112 and contact pads 116 expand toward one another. Once contacting, the metal atoms from the contact pads 112 and the contact pads 116 are diffused into each other and form the connection. In this situation, the dishing (e.g., erosion at a portion of the contact pad relative to another portion of the contact pad or the dielectric material) of contact pads 112 and contact pads 116 must be precisely controlled to prevent over-expansion or under-expansion.

In contrast to these implementations, the techniques disclosed herein utilize a separate deposition process to form interconnects between the contact pads 112 and the contact pads 116. The ALD process is an additive process where the conductive material 122 can be selectively added on top of contact pads 112 and contact pads 116 until the gap between them is filled. Thus, a larger margin of dishing is allowed for the contact pads 112 and contact pads 116, and this dishing can be present even after the conductive material 122 is deposited. In this way, the risk of under-expanded or over-expanded interconnects can be reduced, thereby improving the robustness of the semiconductor device assembly 100. Moreover, the conductive material 122 can adapt to misalignment of the contact pads 112 and contact pads 116 due to its selective adding ability.

In yet another aspect, the conductive material 122 and the contact pads 112 or the contact pads 116 can include different conductive materials. For example, the contact pads 112 or the contact pads 116 can include copper, and the conductive material 122 can include cobalt, gold, silver, or any other conductive material. In some embodiments, the conductive material 122 may be continuous (e.g., seamless) and void of metal-metal bonds, such as those formed through hybrid bonding, as no diffusion occurs between the contact pads 112 and the contact pads 116 to form the interconnects. Moreover, given that ALD can deposit the conductive material 122 slowly, the conductive material 122 can deposit not only vertically but radially on the conductive material 122 that has already been deposited, causing the conductive material 122 to expand into a gap between the layer of dielectric material 110 and the layer of dielectric material 114. In this way, the conductive material 122, at some portions, can be wider than the contact pads 112 or the contact pads 116.

As discussed above, the spacer 118 need not cover the entire surface of the layer of dielectric material 110 or the layer of dielectric material 114. As a result, gaps may be present between the layer of dielectric material 110, the layer of dielectric material 114, the spacer 118, and the conductive material 122. In some cases, gap fill 124 can be used to fill this gap. In doing so, the semiconductor device assembly 100 can be further supported. The gap fill 124 can include a dielectric material or a polymer. If the gap fill 124 includes a dielectric material, the dielectric material may be the same as or different from a dielectric material used for the spacer 118. Similarly, if the gap fill 124 includes a polymer, the polymer may be the same as or different from the polymer used for the spacer 118. In some cases, the gap fill 124 can include a dielectric material disposed through ALD.

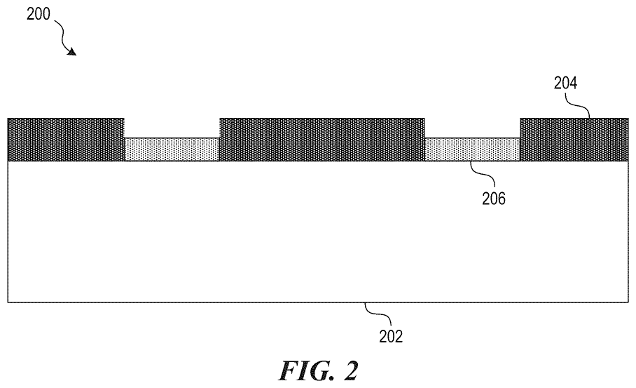

This disclosure now turns to a series of steps for fabricating a semiconductor device assembly in accordance with an embodiment of the present technology. Specifically, FIGS. 2-6 illustrate simplified schematic plan and cross-sectional views of a series of steps for fabricating a semiconductor device assembly in accordance with an embodiment of the present technology. The steps are illustrated with respect to a specific embodiment for ease of description. However, the steps described with respect to FIGS. 2-6 could be performed to fabricate semiconductor device assemblies in accordance with other embodiments.

FIG. 2 illustrates a simplified schematic cross-sectional view of a semiconductor device assembly 200 that includes a substrate 202 (e.g., wafer-level substrate, die-level substrate). In aspects, the semiconductor device assembly 200 can include a wafer of semiconductor dies or a singulated semiconductor die. A layer of dielectric material 204 is disposed at a side of the substrate 202 (e.g., a front side or a back side). Contact pads 206 are disposed at the side of the substrate 202 to enable additional circuit components (e.g., a semiconductor die) to be coupled thereat. The layer of dielectric material 204 includes openings through which contact pads 206 are exposed. The contact pads 206 can be recessed (e.g., 5-10 nanometers) from the layer of dielectric material 204, for example, due to dishing from CMP. In aspects, the layer of dielectric material 204 need not be planarized because the layer of dielectric material 204 does not contact a layer of dielectric material at an additional die and thus does not need a planar surface to improve adhesion.

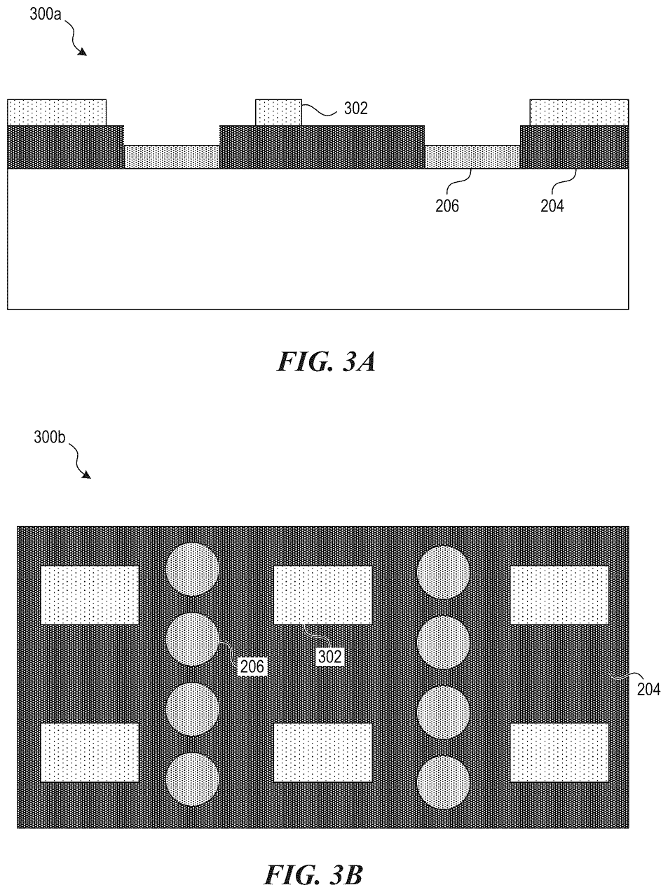

FIG. 3A illustrates a simplified schematic cross-sectional view of a semiconductor device assembly 300a after at least one spacer 302 is disposed at the layer of dielectric material 204. FIG. 3B illustrates a simplified schematic plan view of an upper surface of a semiconductor device assembly 300b. The at least one spacer 302 can be disposed at an upper surface of the layer of dielectric material 204. The at least one spacer 302 can include multiple stand-alone islands separated from one another. As illustrated in FIG. 3B, the at least one spacer 302 does not cover the entire upper surface of the layer of dielectric material 204. In this way, the at least one spacer 302 can have a cross-sectional area coplanar with the upper surface (the surface illustrated in FIG. 3B) that is smaller than the area of the upper surface of the layer of dielectric material 204. The at least one spacer 302 can extend above the upper surface of the layer of dielectric material 204 by a consistent amount (e.g., less than 100 nanometers, less than 200 nanometers, less than 500 nanometers).

The at least one spacer 302 can be disposed through any appropriate technique. For example, the at least one spacer 302 can be deposited using photolithography. The at least one spacer 302 can include a dielectric material or a polymer. In some cases, an upper surface of the at least one spacer 302 can be planarized using CMP. In doing so, the upper surface of the at least one spacer 302 can provide a planar contact surface at which an additional semiconductor die can be coupled.

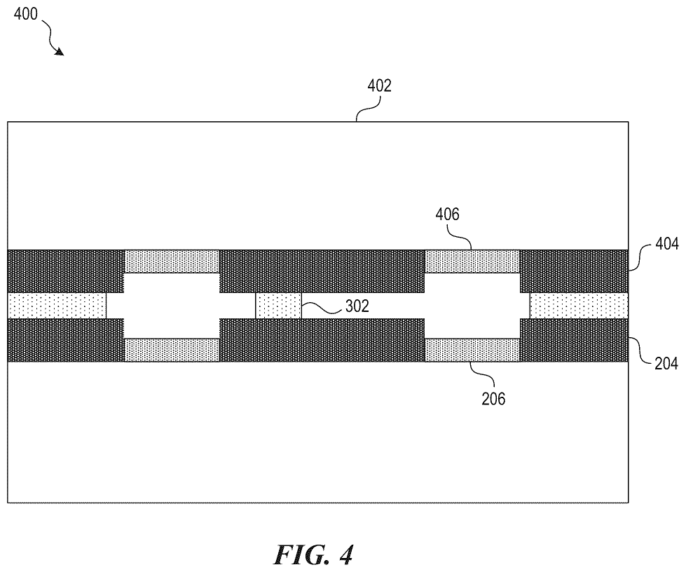

FIG. 4 illustrates a simplified schematic cross-sectional view of a semiconductor device assembly 400. The semiconductor device assembly 400 includes a substrate 402 implementing a semiconductor die. In some implementations, the substrate 402 is a wafer-level substrate implementing multiple semiconductor dies or a die-level substrate implementing a single, singulated semiconductor die. In this way, the semiconductor device assembly 400 can be formed through wafer-to-wafer bonding, chip-to-wafer bonding, or chip-to-chip bonding. A layer of dielectric material 404 is disposed at a side of the substrate 402. The layer of dielectric material 404 has openings, through which contact pads 406 are exposed. The contact pads 406 correspond to the contact pads 206. The layer of dielectric material 404 faces the layer of dielectric material 204. The layer of dielectric material 404 is brought into contact with a coupling surface of the spacer 302. In this way, the spacer 302 may maintain the gap between the semiconductor dies. In some cases, the layer of dielectric material 404 is directly bonded with the spacer 302. For example, the spacer 302 can include a dielectric material, and the spacer 302 and the layer of dielectric material 404 can form a fusion bond. Alternatively, the spacer 302 can include a polymer, and the spacer 302 can bond with the layer of dielectric material 404 through heating or through an adhesive.

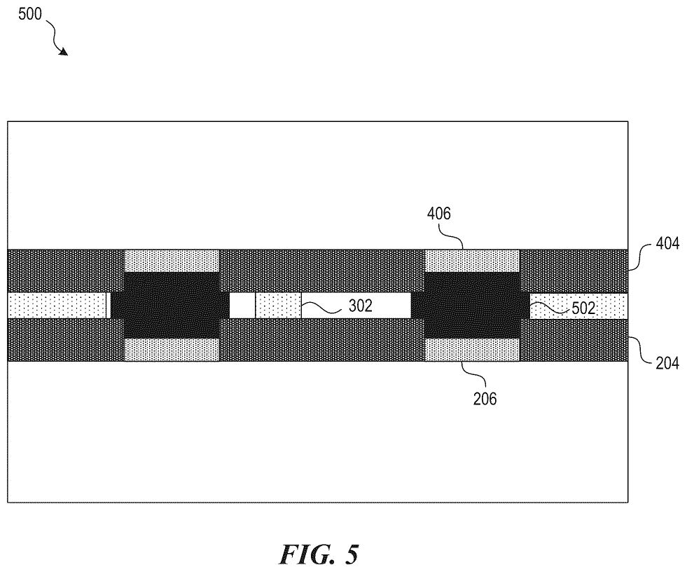

FIG. 5 illustrates a simplified schematic cross-sectional view of a semiconductor device assembly 500 after a conductive material 502 is disposed between the contact pads 206 and the contact pads 406. In aspects, the conductive material 502 is disposed through ALD. In some cases, ALD can enable selective deposition at particular locations. In this way, the conductive material 502 can be selectively deposited in the narrow gap between the contact pads 206 and the contact pads 406, but outside the lateral location of the contact pads 206 and the contact pads 406. For example, the conductive material 502 can be deposited in a gap less than 100 nanometers, less than 200 nanometers, less than 500 nanometers, etc. The conductive material 502 can include any number of conductive materials. For example, the conductive material 502 can be a different material than the material used to implement the contact pads 206 or the contact pads 406. As a specific example, the conductive material 502 can include cobalt.

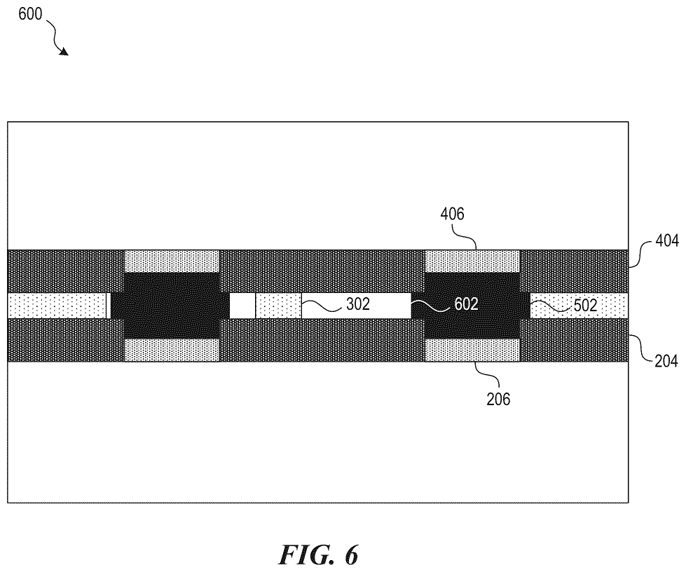

FIG. 6 illustrates a simplified schematic cross-sectional view of a semiconductor device assembly 600 after a gap fill 602 is disposed. Given that the spacer 302 does not necessarily cover the entire surface of the layer of dielectric material 204 and the conductive material 502 is selectively deposited between the contact pads 206 and the contact pads 406, a gap may be present between the layer of dielectric material 204, the layer of dielectric material 404, the spacer 302, and the conductive material 502. The gap fill 602 can be disposed in the gap. For example, the gap fill 602 can be deposited using ALD. In some cases, the gap fill 602 can include a dielectric material or a polymer. By disposing the gap fill 602, the mechanical strength of the semiconductor device assembly 600 can be improved and electrical contact with the conductive material 502 can be prevented.

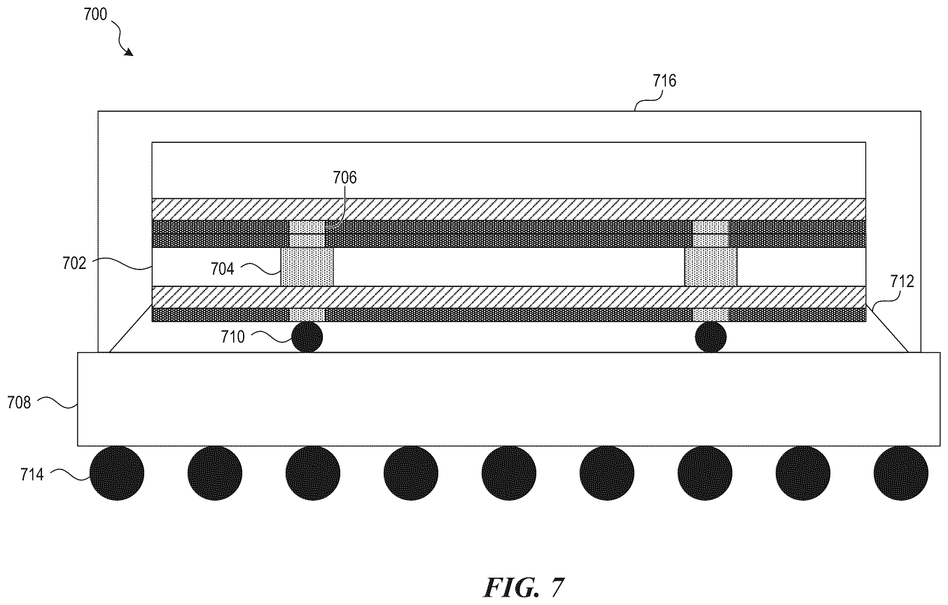

FIG. 7 illustrates a simplified schematic cross-sectional view of a semiconductor device assembly 700 that includes a stack of semiconductor dies 702 (e.g., singulated from two coupled semiconductor wafers) packaged into a semiconductor device. The semiconductor dies 702 can be coupled in a front-to-front arrangement, a front-to-back arrangement, or a back-to-back arrangement. One or more of the semiconductor dies 702 can include TSVs 704 to couple contact pads at a back side with a metallization layer (e.g., with traces, lines, vias, or other connection structures) at the front side. In aspects, interconnects 706 electrically coupling the semiconductor dies 702 can be formed through the techniques disclosed herein (e.g., through ALD deposition using a spacer).

The semiconductor dies 702 may be coupled with a package-level substrate 708 (e.g., printed-circuit board (PCB), interposer, another semiconductor die). Connective structures 710 (e.g., solder balls, solder bumps, conductive pillars) can be disposed between contact pads at a lower side of a bottom semiconductor die of the semiconductor dies 702 and contact pads (not shown) at an upper side of the package-level substrate 708 to implement interconnects that electrically couple the semiconductor dies 702 and the package-level substrate 708. An underfill material 712 (e.g., capillary underfill) can be provided between a bottom die of the semiconductor dies 702 and the package-level substrate 708 to provide electrical insulation to the connective structures 710 and structurally support the semiconductor device assembly 700. The package-level substrate 708 can include internal routing circuity (e.g., traces, lines, vias, and other connection structures) that connects the contact pads at the upper side to contact pads at the lower side. Connective structures 714 may be disposed at the contact pads at the lower side to provide external connectivity to other devices (e.g., on a motherboard). The semiconductor device assembly 700 can further include an encapsulant material 716 (e.g., mold resin compound or the like) that at least partially encapsulates the stack of semiconductor dies 702 and the package-level substrate 708 to prevent electrical contact therewith or provide mechanical strength to the semiconductor device assembly 700.

Although in the foregoing example embodiment semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with, for example, a vertical stack of semiconductor dies or a plurality of semiconductor dies, mutatis mutandis.

In accordance with one aspect of the present disclosure, the semiconductor devices illustrated in the assemblies of FIGS. 1-7 could include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could include memory dies of a same kind (e.g., both NAND, both DRAM) or memory dies of different kinds (e.g., one DRAM and one NAND). In accordance with another aspect of the present disclosure, the semiconductor dies of the assemblies illustrated and described above could be logic dies (e.g., controller dies, processor dies), or a mix of logic and memory dies (e.g., a memory controller die and a memory die controlled thereby).

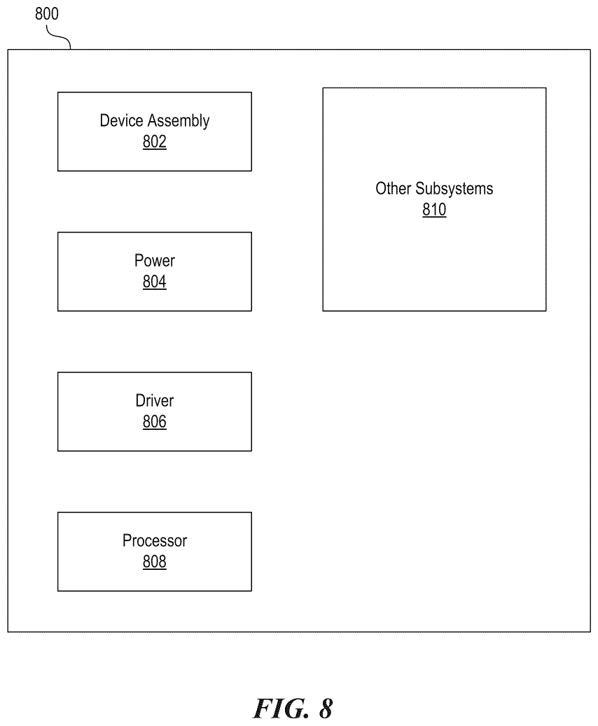

Any one of the semiconductor devices and semiconductor device assemblies described above with reference to FIGS. 1-7 can be incorporated into any of a myriad of larger or more complex systems, a representative example of which is system 800 shown schematically in FIG. 8. The system 800 can include a semiconductor device assembly 802 (e.g., a discrete semiconductor device), a power source 804, a driver 806, a processor 808, and other subsystems or components 810. The semiconductor device assembly 802 can include features generally similar to those of the semiconductor device assemblies described above with reference to FIGS. 1-7. The resulting system 800 can perform any of a wide variety of functions, such as memory storage, data processing, or other suitable functions. Accordingly, representative systems 800 can include, without limitation, hand-held devices (e.g., mobile phones, tablets, digital readers, and digital audio players), computers, vehicles, appliances, or other products. Components of the system 800 may be housed in a single unit or distributed over multiple, interconnected units (e.g., through a communications network). The components of the system 800 can also include remote devices and any of a wide variety of computer-readable media.

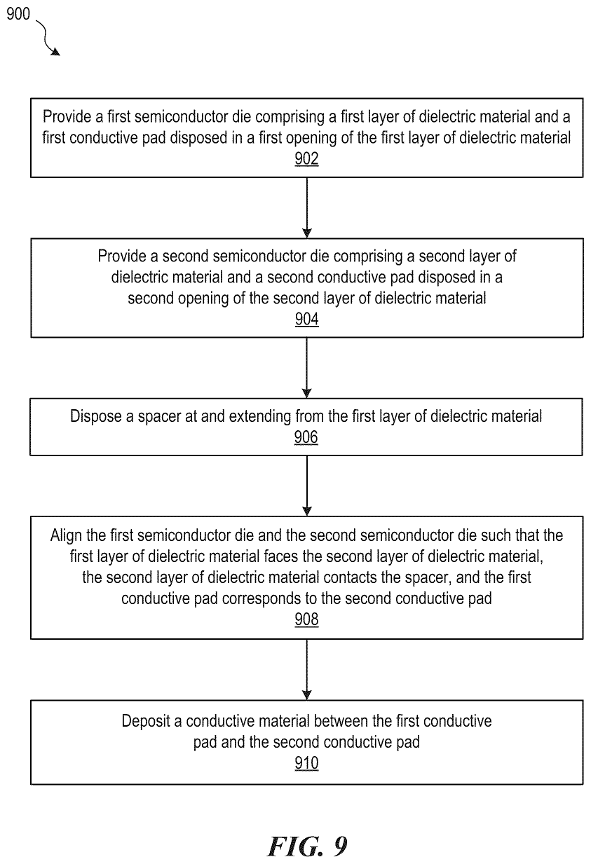

FIG. 9 illustrates an example method 900 for fabricating a semiconductor device assembly in accordance with an embodiment of the present technology. Although illustrated in a particular configuration, one or more operations of the method 900 may be omitted, repeated, or reorganized. Additionally, the method 900 may include additional operations not illustrated in FIG. 9, for example, operations detailed in one or more other methods described herein.

At 902, a first semiconductor die is provided. The first semiconductor die includes a first layer of dielectric material and a first conductive pad disposed in a first opening of the first layer of dielectric material. At 904, a second semiconductor die is provided. The second semiconductor die includes a second layer of dielectric material and a second conductive pad disposed in a second opening of the second layer of dielectric material. At 906, a spacer is disposed at the first layer of dielectric material. The spacer extends from the first layer of dielectric material. At 908, the first semiconductor die and the second semiconductor die are aligned such that the first layer of dielectric material faces the second layer of dielectric material, the second layer of dielectric material contacts the spacer, and the first conductive pad corresponds to the second conductive pad. At 910, a conductive material is deposited (e.g., using ALD) between the first conductive pad and the second conductive pad to implement an interconnect electrically coupling the first semiconductor die and the second semiconductor die. In doing so, a reliable semiconductor device can be assembled.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, ALD, or other suitable techniques. Similarly, materials can be removed, for example, using plasma etching, wet etching, CMP, or other suitable techniques.

The technology disclosed herein relates to semiconductor devices, systems with semiconductor devices, and related methods for manufacturing semiconductor devices. The term “semiconductor device” can refer to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or three-dimensional interface (3DI) applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or subregions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A method for fabricating a semiconductor device assembly, comprising:
providing a first semiconductor die comprising:
a first layer of dielectric material; and
a first conductive pad disposed in a first opening of the first layer of dielectric material;
providing a second semiconductor die comprising:
a second layer of dielectric material; and
a second conductive pad disposed in a second opening of the second layer of dielectric material;
disposing a spacer at and extending from the first layer of dielectric material;
aligning the first semiconductor die and the second semiconductor die such that the first layer of dielectric material faces the second layer of dielectric material, the second layer of dielectric material contacts the spacer, and the first conductive pad corresponds to the second conductive pad; and
depositing, using atomic layer deposition, a conductive material between the first conductive pad and the second conductive pad.

2. The method of claim 1, further comprising depositing, using atomic layer deposition, a polymer or a dielectric material between the first layer of dielectric material, the second layer of dielectric material, the conductive material, and the spacer.

3. The method of claim 1, wherein the spacer is disposed at only a portion of an exposed surface of the first layer of dielectric material.

4. The method of claim 1, further comprising forming a direct bond between the spacer and the second layer of dielectric material.

5. The method of claim 1, wherein the spacer comprises a dielectric material or a polymer.

6. The method of claim 1, wherein the first conductive pad comprises copper and the conductive material comprises cobalt.

7. The method of claim 1, further comprising thinning the spacer using chemical-mechanical planarization.

8. A semiconductor device assembly, comprising:
a first semiconductor die comprising:
a first layer of dielectric material; and
a first conductive pad disposed in a first opening of the first layer of dielectric material;
a second semiconductor die comprising:
a second layer of dielectric material facing the first layer of dielectric material; and
a second conductive pad disposed in a second opening of the second layer of dielectric material and corresponding to the first conductive pad;
a spacer disposed at and extending from the first layer of dielectric material to the second layer of dielectric material; and
a conductive material disposed between the first conductive pad and the second conductive pad to implement an interconnect electrically coupling the first semiconductor die and the second semiconductor die, the conductive material at least partially extending into a gap between the first layer of dielectric material and the second layer of dielectric material.

9. The semiconductor device assembly of claim 8, wherein the first conductive pad is recessed from the first layer of dielectric material.

10. The semiconductor device assembly of claim 9, wherein the first conductive pad is recessed from the first layer of dielectric material by greater than 5 nanometers.

11. The semiconductor device assembly of claim 8, wherein the first conductive pad and the conductive material comprise different conductive materials.

12. The semiconductor device assembly of claim 11, wherein the first conductive pad comprises copper and the conductive material comprises cobalt.

13. The semiconductor device assembly of claim 8, wherein the spacer is disposed at only a portion of a surface of the first layer of dielectric material that faces the second layer of dielectric material.

14. The semiconductor device assembly of claim 8, further comprising a polymer or a dielectric material disposed between the first layer of dielectric material, the second layer of dielectric material, the conductive material, and the spacer.

15. The semiconductor device assembly of claim 8, wherein the spacer comprises a polymer or a dielectric material.

16. The semiconductor device assembly of claim 8, wherein the spacer has a thickness less than 0.5 microns.

17. The semiconductor device assembly of claim 8, wherein the conductive material is formed using an atomic layer deposition process.

18. The semiconductor device assembly of claim 8, wherein the interconnect is continuous between the first conductive pad and the second conductive pad and is void of metal-metal bonds.

19. The semiconductor device assembly of claim 8, wherein the conductive material is a tin-free and lead-free material.

20. A method for fabricating a semiconductor device assembly, comprising:
providing a first semiconductor die comprising:
a first layer of dielectric material; and
a first conductive pad disposed in a first opening of the first layer of dielectric material;
providing a second semiconductor die comprising:
a second layer of dielectric material; and
a second conductive pad disposed in a second opening of the second layer of dielectric material;
disposing a spacer at and extending from the first layer of dielectric material;
coupling the spacer to the second layer of dielectric material such that the first layer of dielectric material faces the second layer of dielectric material and the first conductive pad corresponds to the second conductive pad;
depositing, using atomic layer deposition, a conductive material between the first conductive pad and the second conductive pad; and
depositing, using atomic layer deposition, a polymer or a dielectric material at least partially between the first layer of dielectric material and the second layer of dielectric material.
